(19) United States
(12) Patent Application Publication
(10) Pub. No.: US 2026/0344240 A1
(43) Pub. Date: Oct. 29, 2026

(54) DISPLAY APPARATUS AND METHOD OF FABRICATION THEREOF

(71) Applicant: LG Display Co., Ltd., Seoul (KR)

(72) Inventors: Joo-Hwan KIM, Paju-si (KR); Soo-Bin BAE, Paju-si (KR); Min-Kyoo KIM, Paju-si (KR)

(21) Appl. No.: 19/656,256

(22) Filed: Apr. 23, 2026

(30) Foreign Application Priority Data
Apr. 29, 2025 (KR) 10-2025-0055983

(51) Int. Cl. H10K 59/40; H10K 59/12; H10K 59/122; H10K 59/124; H10K 59/131; H10K 59/80; H10K 77/10; H10K 102/00

(52) U.S. Cl. CPC H10K 59/40; H10K 59/1201; H10K 59/122; H10K 59/124; H10K 59/131; H10K 59/873; H10K 77/111; H10K 2102/351

(57) ABSTRACT

A display apparatus includes a thin film transistor and a light emitting device disposed in each of the plurality of sub-pixels, an encapsulation layer disposed above the light emitting device, a touch sensor disposed on the encapsulation layer, a link line extending from the non-display area to the touch sensor, and a touch planarization layer disposed on the touch sensor and the link line, wherein an end of the touch planarization layer in the non-display area is disposed directly on the bank layer in the non-display area.

### CROSS-REFERENCE TO RELATED APPLICATIONS

Pursuant to 35 U.S.C. § 119(a), this application claims the benefit of an earlier filing date and right of priority to Korean Patent Application No. 10-2025-0055983, filed in the Republic of Korea on Apr. 29, 2025, the entire contents of which is hereby expressly incorporated by reference into the present application.

### TECHNICAL FIELD

The present disclosure relates to a display apparatus and a method of fabricating thereof.

### BACKGROUND

A touch panel is a type of input device that is installed in various display apparatuses such as Liquid Crystal Display (LCD), Organic Light Emitting Display (OLED), and Electrophoretic Display (EPD) apparatuses, and allows users to input information by directly contacting the screen with their fingers or pens while looking at the display apparatus.

### SUMMARY

The display apparatus according to present disclosure includes a thin film transistor and a light emitting device disposed in each of the plurality of sub-pixels, an encapsulation layer disposed above the light emitting device, a touch sensor disposed on the encapsulation layer, at least one link line extending from the non-display area to the touch sensor, and a touch planarization layer disposed on the touch sensor and the at least one link line, wherein an end of the touch planarization layer in the non-display area is disposed directly on the bank layer in the non-display area.

The at least one link line includes a first link line extended to the non-display area to be connected electrically to the touch sensor and a second link line connected electrically to the first link line in the non-display area to apply a touch signal to first link line.

The second link line is disposed in first non-display area, and the first link line and the second link line are connected to each other in the first non-display area or the second non-display area.

The thin film transistor includes a semiconductor layer, a gate insulating layer on the semiconductor layer, a gate electrode on the gate insulating layer, an interlayer insulating layer, and source and drain electrodes on the interlayer insulating layer. A first planarization layer is disposed over the thin film transistor, a connection pattern connected electrically to the drain electrode is disposed on the first planarization layer, and a second planarization layer is disposed on the connection pattern.

A contact hole is formed in the second planarization layer so that the first link line and the second link line is electrically connected to each other within the contact hole. In some implementations, the first link line may be made of the same material as a touch electrode of the touch sensor, and the second link line may be made of the same material as the connection pattern.

A contact hole may be formed in the first planarization layer and the second planarization layer so that the first link line and the second link line may be electrically connected to each other within the contact hole. In some implementations, the first link line is made of the same material as a touch electrode of the touch sensor, and the second link line is made of the same material as the source and drain electrodes.

The bank layer in the first non-display area includes a protruded portion that protrudes towards the bending area, a thickness of the protruded portion is smaller than a thickness of a remaining portion of the bank layer, and the end of the touch planarization layer is disposed directly on the protruded portion of the bank layer.

A method of fabricating the display apparatus includes providing a substrate including a display area and a non-display area, where the display area has a plurality of sub-pixels, and where the non-display area includes (i) a second non-display area disposed outside and adjacent to the display area, (ii) a first non-display area outside the second non-display area, and (iii) a bending area between the first non-display area and the second non-display area, forming a first touch line in the non-display area, forming a bank layer between the sub-pixels of display area and in the non-display area, providing a thin film transistor and a light emitting device in sub-pixel, forming an encapsulation layer over the light emitting device except the first non-display area, forming a touch buffer layer on the encapsulation layer, etching the touch buffer layer of the first non-display area to expose a portion of the bank layer to the outside, forming a touch sensor and a second touch line on the touch buffer layer, and forming a touch planarization on the touch sensor and the second touch line, and wherein an end of the touch planarization layer is contacted with an upper surface of the exposed portion of the bank layer.

### BRIEF DESCRIPTION OF THE DRAWINGS

FIG. 1 is a schematic block diagram of an example of a display apparatus according to the present disclosure.

FIG. 2 is the schematic block diagram of an example of a sub-pixel of the display apparatus of FIG. 1.

FIG. 3 is a circuit diagram conceptually illustrating an example of the sub-pixel of the display apparatus according to the present disclosure.

FIG. 4 is a plan view of an example of the display apparatus according to a first implementation of the present disclosure.

FIG. 5 is a partially enlarged plan view of an example of area A of FIG. 4.

FIG. 6 is a cross-sectional view of an example taken along a line I-I′ of FIG. 5.

FIGS. 7A and 7B are enlarged cross-sectional views of an example of region B of FIGS. 6, respectively 7A, is the enlarged cross-sectional view of an example of the display apparatus having a general structure, and FIG. 7B is the enlarged cross-sectional view of an example of the display apparatus according to the present disclosure.

FIGS. 8A to 8F are views illustrating an example of a method of manufacturing the display apparatus according to the present disclosure.

FIG. 9 is the view illustrating an example of the structure of the display apparatus according to a second implementation of the present disclosure.

FIG. 10 is the view illustrating an example of the structure of the display apparatus according to a third implementation of the present disclosure.

### DETAILED DESCRIPTION

The present disclosure relates to a display apparatus and a method of fabricating thereof, and more particularly, to the display apparatus capable of preventing defects due to disconnection of touch lines.

A touch panel can be implemented using either an add-on method to be attached to an outside of the display panel, or an in-cell method to be installed into the inside of the display panel. In particular, in-cell display panels can be utilized to enable slim portable terminals such as smartphones, tablet PCs, and laptop computers.

However, in the in-cell display panel, touch lines are often formed inside the display panel, which can result in a problem that the touch cannot be recognized when a defect occurs in the touch lines that apply the touch signal to the touch panel.

Implementations of the present disclosure can provide a display apparatus and a method of fabricating thereof capable of preventing separation of touch lines that may be caused due to layer separation in a connection area of touch lines

Implementations of the present disclosure can also provide a display apparatus capable of preventing penetration of foreign substances such as moisture from the outside due to cracks generated in the connection area of a touch lines.

Implementations of the present disclosure can also provide an eco-friendly display apparatus that minimizes the emission of harmful substances.

Advantages and features of the present disclosure and methods for achieving them will be made clear from implementations described in detail below with reference to the accompanying drawings. The present disclosure may, however, be implemented in many different forms and should not be construed as being limited to the implementations set forth herein, and the implementations are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the implementations of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc. may be used. These terms are only for distinguishing the elements from other elements, and the essence, order, or number of the elements is not limited by the terms. When it is described that a component is “connected” “coupled” or “connected” to another component, the component may be directly connected to the other component, but may be indirectly connected to the other component without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, various example implementations of the present disclosure will be described in detail with reference to the accompanying drawings.

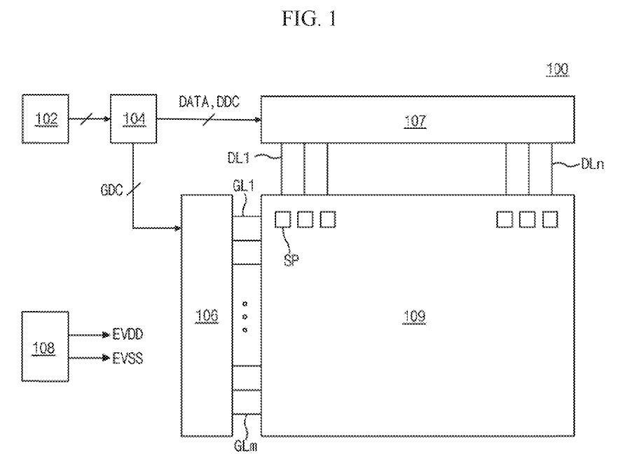

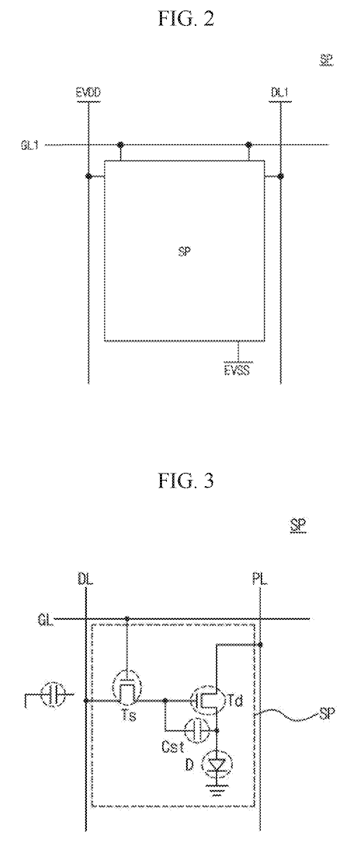

FIG. 1 is the schematic block diagram and FIG. 2 is the schematic block diagram of the sub-pixel of the organic light emitting display apparatus according to the present disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS etc. to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 107, the scan signal from the gate driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to a gate line GL1, a data line DL1, a first power line EVDD, and a second power line EVSS. The number and driving method of transistors and capacitors disposed in the sub-pixel SP are determined according to the configuration of the pixel circuit of the sub-pixel SP.

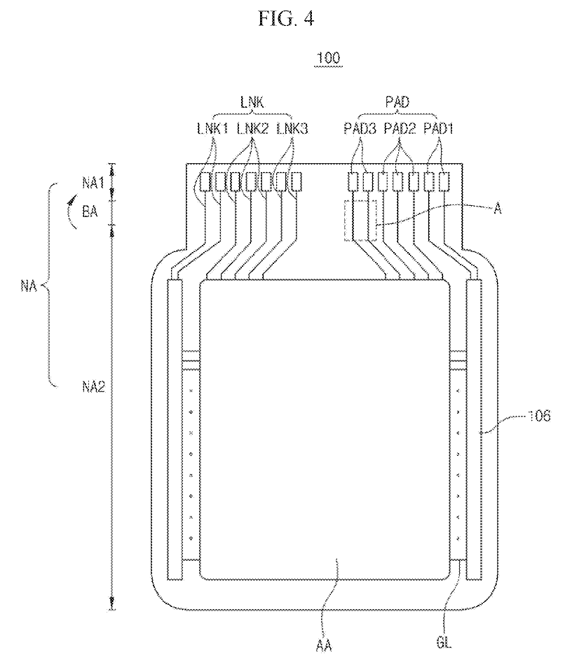

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the organic light emitting device D from the power line PL through the driving thin film transistor Td and then the organic light emitting device D emits light with a luminance proportional to the current flowing through the driving thin film transistor Td. Although not shown in the drawings, a light emission control thin film transistor may be disposed between the driving thin film transistor Td and the organic light emitting device D.

In some implementations, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

Hereinafter, the display apparatus according to the implementation of the present disclosure will be described in detail with reference to the accompanying drawings.

FIG. 4 is a plan view of an example of the display apparatus 100 according to the present disclosure.

As shown in FIG. 4, the display apparatus 100 according to an implementation of the present disclosure includes a display area AA where an image is displayed and a non-display area NA outside the display area AA.

For example, the display apparatus 100 may be a flexible display apparatus. In this case, the substrate of the display apparatus 100 is a flexible substrate and is a base member made of an insulating material for supporting various components of the display apparatus 100. For example, the substrate may be made of a flexible plastic material such as polyimide (PI).

In some implementations, the display apparatus 100 may have a non-rectangular shaped corner area, and the display area AA may have a shape corresponding to the non-rectangular shaped corner area. For example, the corners of the display area AA and the non-display area NA may have a rounded shape. However, the display apparatus 100 of the present disclosure is not limited to this shape, but may be formed in various shapes according to the design of the mounted electronic device.

A pixel P including a plurality of sub-pixels SP1, SP2, and SP3 is disposed in the display area AA. In this case, each of the sub-pixels SP1, SP2, and SP3 may include a red (R) sub-pixel, a green (G) sub-pixel, and a blue (B) sub-pixel. Also, the pixel P may further include a white (W) sub-pixel.

A plurality of gate lines and data lines are arranged in the display area AA to define a plurality of sub-pixels SP in the intersection area of the gate lines and data lines. In each sub-pixel SP1, SP2, and SP3, a thin film transistor as a switching device and a display device for displaying the image are arranged.

The display device may include various display devices. For example, the display device may be an organic light emitting display device, a liquid crystal display device, a quantum dot display device, a micro LED display device, or a mini LED display device.

The non-display area NA is the area in which an image is not displayed. Various signal lines and circuits for driving the display elements of the display area AA are disposed in the non-display area NA. For example, the gate driving unit 106, the data driving unit (not shown), link lines LNK, a plurality of pads PAD, and the like may be disposed in the non-display area NA. The non-display area NA may be a bezel area, and configurations of the present specification are not limited thereto.

In some implementations, the non-display area NA includes a first non-display area NA1, a bending area BA, and a second non-display area NA2. The second non-display area NA2 is the area that is disposed immediately outside and extending from the display area AA. The bending area BA is the area extending from the second non-display area NA2 and may be bent along a horizontal bending line, in a direction as shown by the arrow in FIG. 1. The first non-display area NA1 extends from the bending area BA.

A plurality of link lines LNK, a plurality of pads PAD, and the like may be disposed in the first non-display area NA1. Each of the plurality of pads PAD connects a link line LNK to a flexible film or a printed circuit board. Each link line LNK connects a PAD to the active area AA.

The pad PAD includes a plurality of first pads PAD1, a plurality of second pads PAD2, and a plurality of third pads PAD3. A plurality of first pads PAD1 are disposed on both sides of the first non-display area NA1, and a plurality of second pads PAD2 and third pads PAD3 are disposed at the center of the first non-display area NA1. For example, a plurality of second pads PAD2 may be disposed between a plurality of first pads PAD1, and a plurality of third pads PAD3 may be disposed between a plurality of second pads PAD2.

The link lines LNK include a plurality of first link lines LNK1, a plurality of second link lines LNK2, and a plurality of third link lines LNK3.

A plurality of first pads PAD1 are electrically connected to a plurality of first link lines LNK1. The first link line LNK1 may be the link line connected to the gate driving unit 106.

A plurality of second pads PAD2 are electrically connected to a plurality of second link lines LNK2. The second link line LNK2 may be link line connected to data line, power line, or the like disposed in the display area AA.

A plurality of third pads PAD3 are electrically connected to a plurality of third link lines LNK3. The third link line LNK3 may be a touch link line connected to the touch line.

The gate driving unit 106 is disposed in the second non-display area NA2. The gate driving unit 106 supplies a plurality of scan signals to a plurality of gate lines GLs according to a plurality of gate control signals provided from the timing controlling unit. Although FIG. 4 illustrates that the two gate driving units 106 are disposed on both sides of the display area AA, the number and arrangement of the gate driving units 106 are not limited thereto.

In some implementations, the second non-display area NA2 is an area surrounding t the display area AA and a portion of the second non-display area NA2 can be disposed between the bending area BA and the active area AA. A plurality of link lines LNK such as gate link line, power link line, data link line, and touch link line can be disposed in the second non-display area NA2 to transmit the signal transmitted from a plurality of pads PAD to the display area AA.

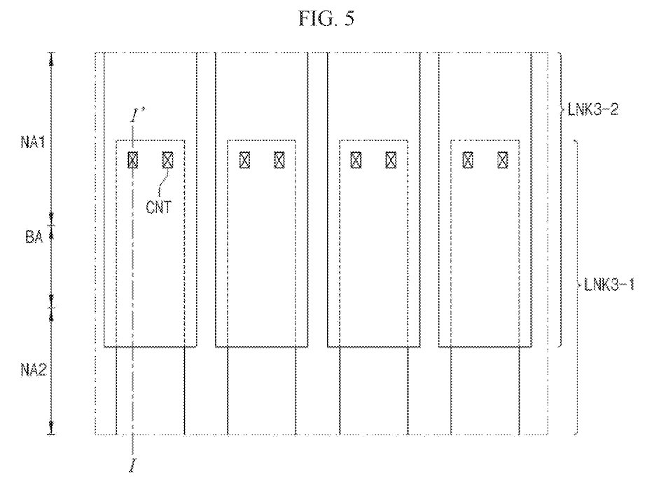

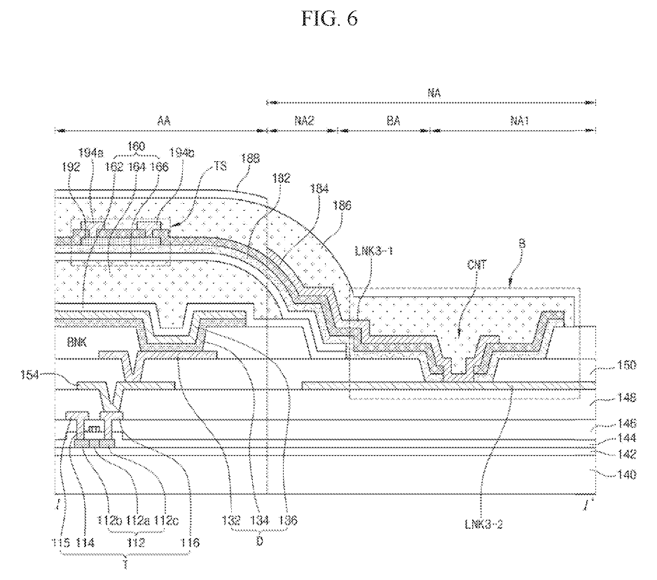

FIG. 5 is an example of a partially enlarged plan view of area A of FIG. 4, showing details of the link lines LNK.

As shown in FIG. 5, the display panel PNL of the display apparatus 100 includes the display area AA and the non-display area NA, and the non-display area NA includes the first non-display area NA1, the second non-display area NA2, and the bending area BA.

The third link line LNK3 is disposed in the first non-display area NA1, the second non-display area NA2, and the bending area BA. The third link line LNK3 applies the touch driving signal to the display panel PNL and receives the touch signal from the touch panel.

Each of a plurality of third link lines LNK3 includes a 3-1 link line LNK3-1 and a 3-2 link line LNK3-2. The 3-1 link line LNK3-1 may be disposed in the second non-display area NA2 and extend to the bending area BA and the second non-display area NA2. The 3-2 link line LNK3-2 may be disposed in the first non-display area NA1 and extend to the bending area BA and the second non-display area NA2, but is not limited thereto.

Although the 3-1 link line LNK3-1 and the 3-2 link line LNK3-2 have different widths to clarify the positional relationship between the two link lines in the drawing, the actual widths of the 3-1 link line LNK3-1 and the 3-2 link line LNK3-2 are the same.

A plurality of contact holes CNT are formed in the first non-display area NA1. As will be described later, the 3-1 link line LNK3-1 and the 3-2 link line LNK3-2 are formed on different layers with an insulating layer interposed therebetween, and the 3-1 link line LNK3-1 and the 3-2 link line LNK3-2 are electrically connected through the contact hole CNT. A plurality of third link lines LNK3 are disposed along the width direction of the bending area BA. In this case, a plurality of third link line2 LNK3 are spaced apart from each other by a predetermined distance d. In the drawing, the contact hole CNT is formed in the first non-display area NA1, but the present disclosure is not limited thereto. The contact hole CNT may be formed in the bending area BA or the second non-display area NA2.

Various insulating layers can be disposed on the upper and lower portions of the third link line LNK3 at the ends of the plurality of third link lines LNK3. In some implementations, the insulating layers are overlapped for each other. The insulating layers may include an inorganic insulating layer and an organic insulating layer. In some scenarios a problem may arise when an inorganic insulating layer and an organic insulating layer are overlapped for each other, because the bonding force between the inorganic insulating layer and the organic insulating layer can decrease due to the boundary properties therebetween. As a result, the layers (e.g., the inorganic insulating layer and the organic insulating layer) can be separated from each other.

When the layers are separated from each other, foreign substances such as moisture can penetrate between the layers. Further exacerbating this problem, one or more cracks can be generated separation of layers, and the penetration of foreign substances can be further facilitated by such cracks. For example, in the example of FIG. 5, the separation of the layers can result in delamination of the ends of the 3-1 link line LNK3-1 disposed above and below the layers, and the delamination of the third link line LNK3 can result in touch defects to the touch panel.

Implementations of the present disclosure can help reduce instances of layer separation at the end of the 3-1 link line LNK3-1, that is, at the connection area between the 3-1 link line LNK3-1 and the 3-2 link line LNK3-2, thereby mitigating defects caused by layer separation.

Hereinafter, example implementations of the display apparatus 100 in which layer separation can be mitigated will be described in detail with reference to the accompanying drawings.

FIG. 6 is a cross-sectional view taken along line I-I' of FIG. 5, which specifically illustrates an example of the structure of the display apparatus 100 according to an implementation of the present disclosure. In the drawing, only a portion of the display area AA and a portion of the non-display area NA are shown for convenience of description.

As shown in FIG. 6, the substrate 140 includes the display area AA and also includes the non-display area NA which includes the first non-display area NA1, the bending area BA, and the second non-display area NA2.

In some implementations, the substrate 140 may be made of the plastic material. For example, the substrate may be made of at least one material of polyimide, polymethylmethacrylate, polyethylene tereththalate, Polyethersulfone, and Polycarbonate, but is not limited thereto.

When the substrate 140 is made of polyimide, the substrate 140 may be made of a plurality of polyimide layers, and an inorganic layer may be further disposed between the polyimide layers, but is not limited thereto.

A buffer layer 142 is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer in each sub-pixel SP1 and SP2. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor pattern 112 through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A first planarization layer 148 is formed on the substrate where the thin film transistor is disposed. The first planarization layer 148 may be formed of the organic material such as photo-acrylic. But it is not limited thereto. The first planarization layer 148 may include a plurality of layers including the inorganic layer and the organic layer.

A connection pattern 154 is disposed on the first planarization layer 148 and is electrically connected to the drain electrode 116 of the thin film transistor T through a contact hole formed in the first planarization layer 148. The connection pattern 154 may be made of metal.

A second planarization layer 150 is formed on the first planarization layer 148 on which a connection pattern 154 is formed. The second planarization layer 150 may be formed of the organic material such as photo-acrylic, but it is not limited thereto. The second planarization layer 150 may include a plurality of layers including the inorganic layer and the organic layer. The second planarization layer 150 may be made of the same material as the first planarization layer 148, but may also be made of a different material.

In the present disclosure, by forming the planarization layer in a two-layer structure including first planarization layer 148 and second planarization layer 150, various electrodes and signal lines can be formed between the first and second planarization layers 148 and 150. Accordingly, since the electrodes can be arranged vertically, the area due to the electrodes and signal line in the sub-pixel can be reduced, and as a result the area of the sub-pixel can be reduced for a high-resolution display apparatus 100.

A light emitting device D is disposed on the second planarization layer 150 in the display area AA. The light emitting device D includes a first electrode 132, a light emitting layer 134 (e.g., an organic layer), and a second electrode 136.

The first electrode 132 is disposed on the second planarization layer 150 and electrically connected to the drain electrode 116 of the thin film transistor through the contact hole formed in the second planarization layer 150. The first electrode 132 may be formed of at least one of silver (Ag), aluminum (Al), gold (Au), molybdenum (Mo), tungsten (W), chromium (Cr), or an alloy thereof.

Further, the first electrode 132 may be formed of a transparent metal oxide material such as indium tin oxide (ITO) or indium zinc oxide (IZO). When the first electrode 132 is formed of the transparent metal oxide, the first electrode 132 may further include a reflective electrode made of an opaque conductive material that reflects light.

The thin film transistor T connected to the first electrode 132 may be a light emission control transistor.

A bank layer BNK is formed at the boundary between the sub-pixels on the second planarization layer 150. The bank layer BNK may be a barrier wall to define sub-pixels. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

Further, the bank layer BNK may include a light absorbing material or a light blocking material. For example, the bank layer BNK may be formed of at least one material that absorbs light of a specific wavelength. The bank layer BNK may have a structure in which at least two layers of a red color filter, a green color filter, and a blue color filter are deposited.

The light emitting layer 134 may be formed in the R, G, and B pixels and may include an R-emitting layer that emits red light, a G-emitting layer that emits green light, and a B-emitting layer that emits blue light. For example, the light emitting layer 134 may include an organic light emitting layer, an inorganic light emitting layer, a nano-sized material layer, a quantum dot, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the semi-transparent conductive material that transmits light. . For example, the second electrode 136 may be made of one or more of the alloys such as LiF/Al, CsF/Al, Mg:Ag, Ca/Ag, Ca:Ag, LiF/Mg:Ag, LiF/Ca/Ag, or LiF/Ca:Ag. Further, the second electrode 136 may be made of the transparent metal oxide material such as ITO or IZO, but is not limited thereto.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 160 is formed on the light emitting device D to seal the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 160 blocks impurities such as the oxygen and the moisture from the outside to prevent defects of the light emitting device D and various electrodes.

The encapsulation layer 160 may be formed of a first encapsulation layer 162, a second encapsulation layer 164, and a third encapsulation layer 166, but is not limited thereto. In some implementations, the encapsulation layer 160 may be formed of two layers or four or more layers.

The first encapsulation layer 162 and the third encapsulation layer 166 each may be made of a single layer or multiple layers including the inorganic materials such as SiOx, SiON, SiNx, etc., and may further include organic materials between the inorganic materials such as SiOx, SiON, SiNx, etc., but are not limited thereto. The second encapsulation layer 164 may be made of epoxy resin.

A touch buffer layer 182 is formed on the encapsulation layer 160, and a touch sensor TS is disposed thereon. The touch sensor TS includes a bridge electrode 192 disposed on the touch buffer layer 182, a touch interlayer insulating layer 184 disposed on the bridge electrode 192, and touch electrodes 194a and 194b disposed on the touch interlayer insulating layer 184.

The touch buffer layer 182 and the touch interlayer insulating layer 184 may be made of the inorganic material. For example, the touch buffer layer 182 and the touch interlayer insulating layer 184 may be made of silicon oxide (SiOx) or silicon nitride (SiNx), but are not limited thereto. The touch buffer layer 182 and the touch interlayer insulating layer 184 are extended to the second non-display area NA2 from the display area AA.

The bridge electrode 192 and the touch electrodes 194a and 194b may be formed of the single layer or the multiple layers made of one or an alloy of molybdenum (Mo), aluminum (Al), chromium (Cr), gold (Au), titanium (Ti), nickel (Ni), neodymium (Nd), and copper (Cu). Further, the bridge electrode 192 and the touch electrodes 194a and 194b may be made of the transparent metal oxide such as ITO or IZO.

The bridge electrode 192 and the touch electrode 194a are electrically connected to each other through the contact hole formed in the touch interlayer insulating layer 184. Although not shown in the drawing, the touch electrodes 194a and 194b may be formed in a mesh shape.

A touch planarization layer 186 is formed on the touch sensor TS to protect the touch sensor TS. The touch planarization layer 186 may be made of the organic material, or may be formed of a plurality of layers of the organic layer and the inorganic layer.

Although the touch sensor TS is disposed on the encapsulation layer 160 in the drawing, but the present disclosure is not limited to this structure. The touch sensor TS may be disposed under the encapsulation layer 160.

Although not shown in the drawing, the 3-1 link line LNK3-1 is disposed on the touch interlayer insulating layer 184 of the display area AA to be electrically connected to the touch electrodes 194a and 194b in the display area AA. In this case, the 3-1 link line LNK3-1 extends from the display area AA to the first non-display area NA1. The 3-2 link line LNK3-2 is disposed on the first planarization layer 148 of the first non-display area NA1. In some implementations, the 3-2 link line LNK3-2 extends from the first non-display area NA1 through the bending area BA to the second non-display area NA2 to input the external touch signal, but the present disclosure is not limited thereto.

The 3-1 link line LNK3-1 and the 3-2 link line LNK3-2 are electrically connected to each other through the contact hole CNT.

The contact hole CNT is formed by removing the second planarization layer 150, so that the 3-2 link line LNK3-2 disposed on the first planarization layer 148 is exposed to the outside through the contact hole CNT.

The 3-1 link line LNK3-1 extends from the display area AA into the contact hole CNT and directly contacts the 3-2 link line LNK3-2, so that the 3-1 link line LNK3-1 and the 3-2 link line LNK3-2 are electrically connected to each other. As a result, the touch signal applied from the outside is supplied to the touch sensor TS through the 3-2 link line LNK3-2 and the 3-1 link line LNK3-1.

The 3-1 link line LNK3-1 may be made of the same metal as the touch electrodes 194a and 194b, but is not limited thereto.

The 3-2 link line LNK3-2 may be formed of the same metal as the connection pattern 154.

A touch planarization layer 186 is formed on the touch sensor TS to protect the touch sensor TS. The touch planarization layer 186 may be made of the organic material, or may be formed of the multiple layers of organic layers and inorganic layers. The touch planarization layer 186 is formed in the display area AA and may extend to the second non-display area NA2, the bending area BA, and a partial area of the first non-display area NA1.

The touch passivation layer 188 is disposed on the touch planarization layer 186. In this case, the touch passivation layer 188 may be formed of the organic material, or the organic layer/inorganic layer may be formed of a plurality of layers, but is not limited thereto. Although not shown in the drawing, a dam DAM is disposed in the second non-display area NA2. Since the organic material forming the second encapsulation layer 164 has fluidity, the organic material may flow out to the outside of the substrate 140 by the fluidity when the second encapsulation layer 164 is formed. Since the dam DAM is formed to surround the display area NA, the organic materials flowing out of the substrate 140 may be contained by the dam DAM when the second encapsulation layer 164 is formed. Therefore, the organic material does not flow out of the substrate 140.

Further, although not shown in the drawing, a micro coating layer may be disposed in the non-display area, especially in the bending area. The micro coating layer is made of the flexible organic material to block moisture from the outside. In addition, the micro coating layer reduces the tensile stress and contraction stress that can be received by the lines by positioning various lines in the bending area close to the neutral plane during the bending process. The touch planarization layer 186 extends from the display area AA to the bending area BA, and the end of the touch planarization layer 186 is disposed directly on the upper surface of the bank layer BNK in the first non-display area NA1. As described above, in the present disclosure, since the end of the touch planarization layer 186 is disposed directly on and contacts the upper surface of the bank layer BNK, this can help prevent the delamination of the touch planarization layer 186, which will be described in detail below.

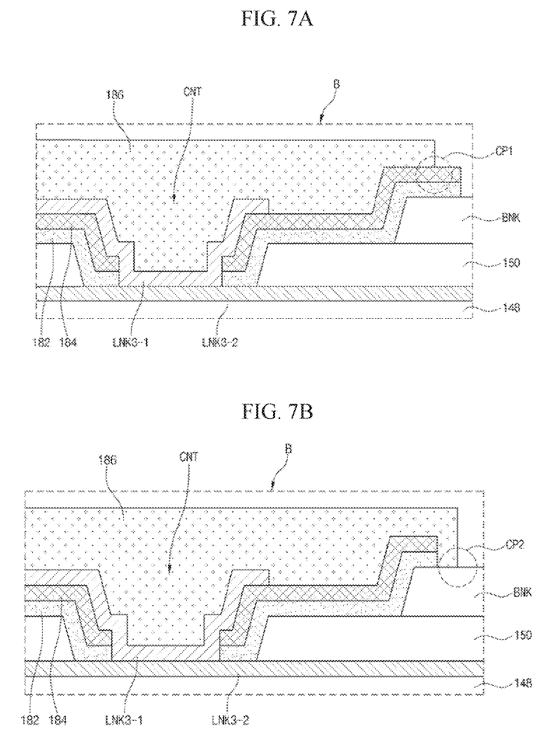

FIGS. 7A and 7B are comparative enlarged cross-sectional views of area B of FIG. 6. In particular, FIG. 7A is an example of the enlarged cross-sectional view showing the contact area of the 3-1 link line LNK3-1 and the 3-2 link line LNK3-2 of the display apparatus having an alternative structure. By contrast, FIG. 7B is the enlarged cross-sectional view showing the contact area of the 3-1 link line LNK3-1 and the 3-2 link line LNK3-2 of the display apparatus according to an implementation of the present disclosure.

As shown in FIG. 7A, in the display apparatus having the alternative structure, the touch buffer layer 182 and the touch interlayer insulating layer 184 are disposed on the bank layer BNK outside the contact hole CNT and extend outward. Therefore, the end of the touch planarization layer 186 is disposed on the interlayer insulating layer 184, so that the end CP1 of the touch planarization layer 186 is directly contacted with the interlayer insulating layer 184.

In scenarios where the touch planarization layer 186 is made of the organic material and the interlayer insulating layer 184 is made of the inorganic material, a problem can arise where the boundary properties between the touch planarization layer 186 and the interlayer insulating layer 184 become deteriorated so that the adhesion between the touch planarization layer 186 and the interlayer insulating layer 184 is decreased. As a result, problems can arise in the display apparatus of this structure, since the end of the touch planarization layer 186 is easily delaminated from the interlayer insulating layer 184, and a crack can form in the touch planarization layer 186 and/or the 3-1 link line LKN3-1 may be damaged.

On the other hand, as shown in FIG. 7B, in the display apparatus 100 according to implementations of the present disclosure, the end of the touch planarization layer 186 (made of organic material) is disposed directly on the bank layer BNK (also made of organic material) in the contact area of the touch line, the adhesion between the touch planarization layer 186 and the bank layer BNK is improved, and can prevent the delamination from the touch planarization layer 186. In particular, as shown in the example of FIG. 7B, since the 3-2 link line LKN3-2 is disposed on the first planarization layer 148 and the contact hole CNT is formed in the second planarization layer 150 above the 3-2 link line LKN3-2, the 3-2 link line LKN3-2 is exposed to the outside through the contact hole CNT. In this case, the touch buffer layer 182 and the touch interlayer insulating layer 184 are formed on the second planarization layer 150 and on the bank layer BNK, and the touch buffer layer 182 and the touch interlayer insulating layer 184 extend inside the contact hole CNT. However, the touch buffer layer 182 and the touch interlayer insulating layer 184 are etched in the central region of the contact hole CNT to expose the 3-2 link line LKN3-2 to the outside.

Since the bank layer BNK is formed on the second planarization layer 150 and the end of the bank layer BNK is spaced apart from the contact hole CNT by a predetermined distance, the second planarization layer 150 and the bank layer BNK may be formed in a step shape.

Since the 3-1 link line LKN3-1 is disposed inside the contact hole CNT to be electrically connected to the 3-2 link line LKN3-2, the external touch signal is supplied to the touch sensor TS through the 3-2 link line LKN3-2 and the 3-1 link line LKN3-1.

The touch planarization layer 186 is disposed above the contact hole CNT. The touch planarization layer 186 extends from the display area AA to the second non-display area NA2, and the end CP2 is disposed directly on the bank layer BNK.

The bank layer BNK and the touch planarization layer 186 may be formed of the organic material. Therefore, since the touch planarization layer 186 is disposed directly on and contacts the bank layer BNK, the organic material of the touch planarization layer 186 and the organic material of the bank layer BNK are contacted with each other at the end of the touch planarization layer 186. As a result, since the organic materials are bonded to each other at the interface between the bank layer BNK and the touch planarization layer 186, this can help prevent the delamination of the end of the touch planarization layer 186.

As described above, in the display apparatus 100 according to the present disclosure, since the end of the touch planarization layer 186 made of the organic material is disposed directly on the bank layer BNK made of the organic material in the contact area of the touch line, the adhesion between the touch planarization layer 186 and the bank layer BNK is improved to help prevent the delamination from the touch planarization layer 186, and as a result the defects such as cracks or the damage of the touch line due to the delamination of the touch planarization layer 186 can be prevented.

Hereinafter, a method of manufacturing the display apparatus 100 according to the present disclosure will be described in detail with reference to the accompanying drawings.

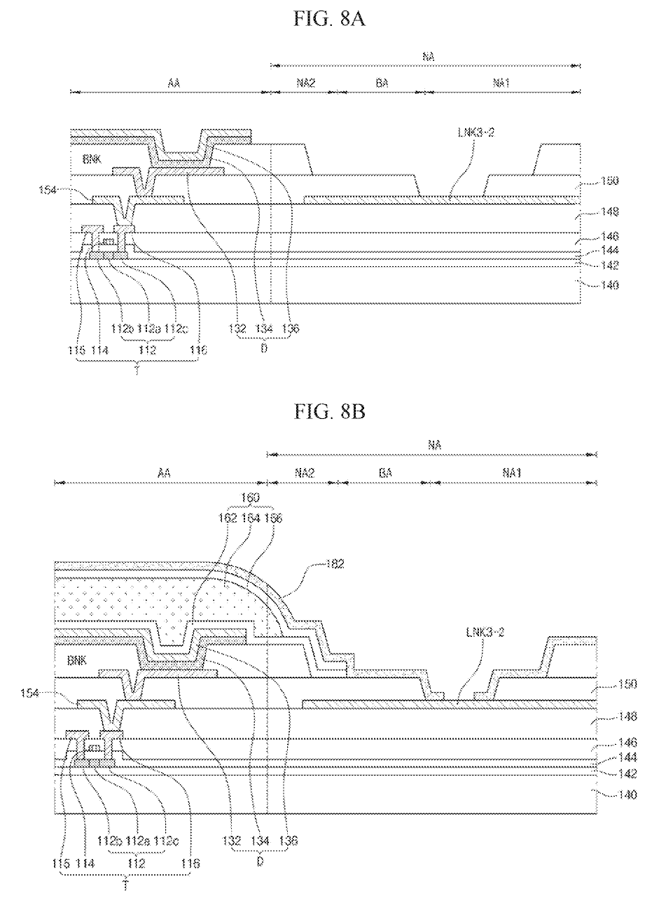

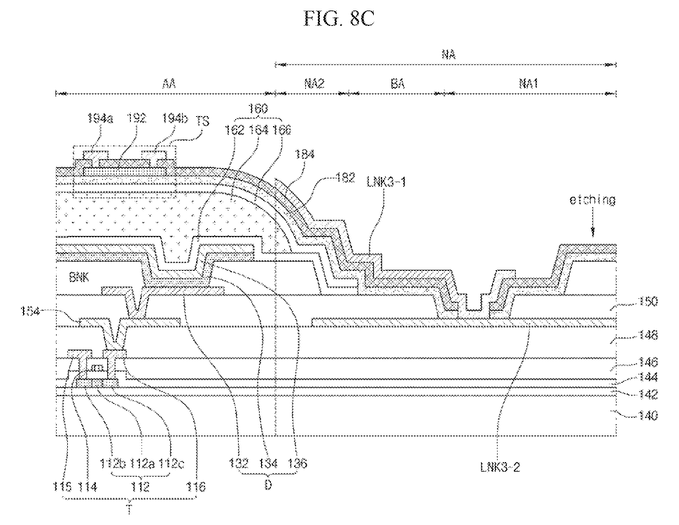

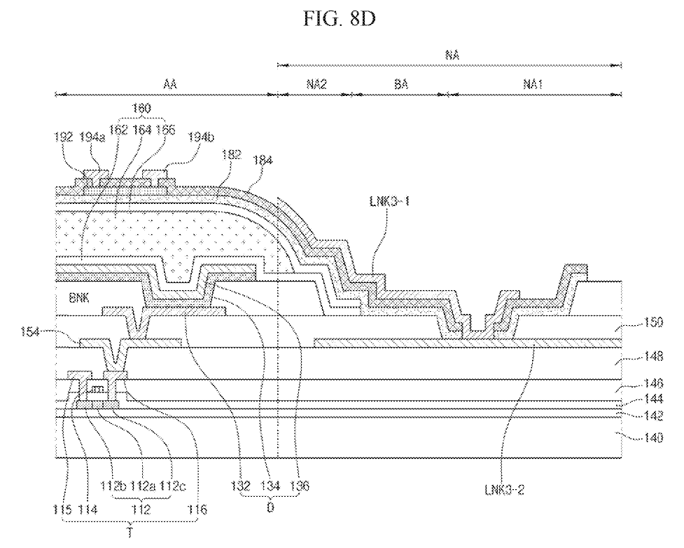

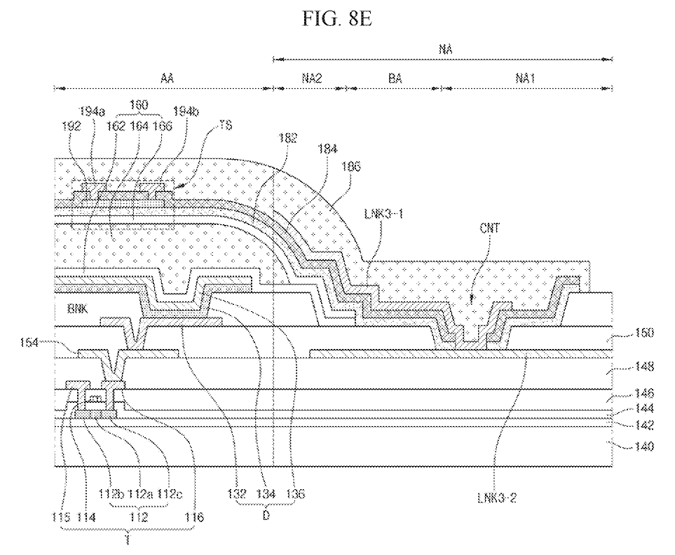

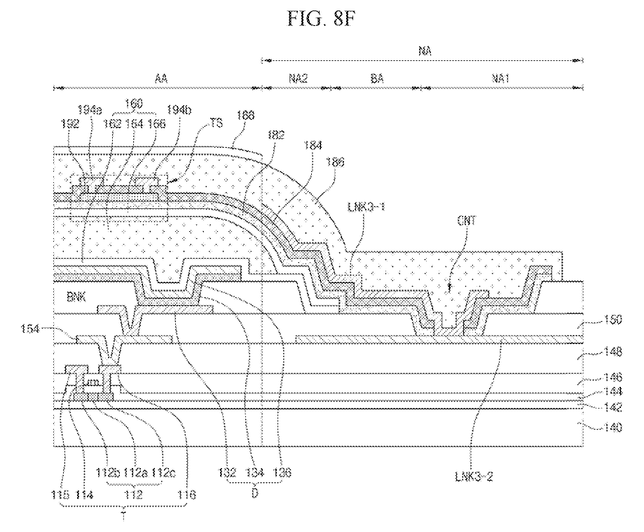

FIGS. 8A to 8F are views illustrating an example of the method of manufacturing the display apparatus 100 according to the present disclosure.

As shown in FIG. 8A, the buffer layer 142 is formed over the entire substrate 140. The substrate 140 may be made of the hard material such as the glass or the plastic material such as the plastic material may include a polyimide, a polymethylmethacrylate, a polyethylene tereththalate, a Polyethersulfone, and a Polycarbonate. The buffer layer 142 may be formed of the single layer of SiNx or SiOx, or multiple layers thereof.

Thereafter, the poly-crystalline semiconductor material such as poly-silicon or the oxide semiconductor material such as etching IGZO (Indium-gallium-zinc-oxide), IZO (Indium-zinc-oxide), IGTO (Indium-gallium-tin-oxide), and IGO (Indium-gallium-oxide) is deposed and etched to form the semiconductor layer 112 on the buffer layer 142. Further, the impurities are doped into both sides of the semiconductor layer 112 to form the channel region 112a, the source region 112b, and the drain region 112c.

Subsequently, the gate insulating layer 144 is formed by depositing the inorganic material such as SiOx or SiNx, and then the metal such as molybdenum (Mo), aluminum (Al), chromium (Cr), gold (Au), titanium (Ti), nickel (Ni), Neodymium (Nd) and copper (Cu) are deposited by the sputtering method and etched by the wet etching method to form the gate electrode 114. Thereafter, the organic material such as photo acrylic material or the inorganic material such as SiNx or SiOx is deposited on the gate electrode 114 to form the interlayer insulating layer 146, and then the interlayer insulating layer 146 over the source region 112b and the drain region 112c of the semiconductor layer 112 is dry-etched to form the contact holes therein.

Subsequently, the metal such as Cr, Mo, Ta, Cu, Ti, Al, or an Al alloy is deposited by the sputtering method and etched to form the source electrode 115 and the drain electrode 116 which are respectively ohmic-contacted to the source region 112b and the drain region 112c of the semiconductor layer 112 through the contact holes in each of the first to third sub-pixels SP1, SP2, and SP3.

Thereafter, the planarization layer 148 is formed on the interlayer insulating layer 146 by depositing the organic material such as photo-acryl on the source electrode 115 and the drain electrode 116, and then the first planarization layer 148 on the drain electrode 116 is dry-etched to form the contact hole.

Thereafter, the single layer or the multi-layers made of the metal such as molybdenum (Mo), aluminum (Al), chromium (Cr), gold (Au), titanium (Ti), nickel (Ni), neodymium (Nd), and copper (Cu), the alloys thereof, or the metal oxide such as indium tin oxide (ITO) or indium zinc oxide (IZO) is deposited and then etched to form connection pattern 154. In this case, the connection pattern 154 is electrically connected to the drain electrode 116 of the thin film transistor T through the contact hole formed in the first planarization layer 148.

Subsequently, the organic material such as photoacrylic is deposited to form the second planarization layer 150, and then the contact hole is formed by dry etching the second planarization layer 150 above the connection pattern 154.

Thereafter, metals such as silver (AG), aluminum (Al), gold (Au), molybdenum (Mo), tungsten (W), and chromium (Cr) are stacked by the sputtering method and etched by the wet etching method to form the first electrode 132 on the second planarization layer 150. In this case, the first electrode 132 is electrically connected to the drain electrode 116 of the thin film transistor through the contact hole.

Thereafter, at least one material of the inorganic insulating material such as SiNx or SiOx, the organic material such as BCB (BenzoCycloButene), acrylic resin, epoxy resin, phenolic resin, polyamide resin, and polyimide resin, and the photoresist including the black pigment is deposited on the second planarization layer 150 and dry-etched to form the bank layer BNK.

Subsequently, the light emitting layer 134 is formed by depositing a light emitting material on the first electrode 132, and then the metal oxide such as ITO or IZO is deposited to form the second electrode 136.

As shown in FIG. 8B, the encapsulation layer 160 including the first encapsulation layer 162, the second encapsulation layer 164, and the third encapsulation layer 166 is formed over the light emitting device D. In this case, the first encapsulation layer 162 and the third encapsulation layer 166 may be formed by depositing inorganic materials with a chemical vapor deposition (CVD) process.

When the first encapsulation layer 162 and the third encapsulation layer 166 are formed, although not shown in the drawing, the inorganic materials are deposited while the first non-display area NA and the bending area BA are blocked by the blocking member such as a mask, so that the first encapsulation layer 162 and the third encapsulation layer 166 may be formed over the entire substrate 140 except for the first non-display area NA and the bending area BA.

The second encapsulation layer 164 may be formed by directly coating the organic material on the first encapsulation layer 162 by a spin coating method or a dispensing method.

Subsequently, the inorganic material such as SiOx or SiNx is deposited and etched on the third encapsulation layer 166 to form the touch buffer layer 182 thereon. In some implementations, the touch buffer layer 182 is extended from the display area AA to the bending area BA so that the touch buffer layer 182 is extended to a partial area inside the contact hole CNT, and the second touch link line LNK3-2 is exposed to the outside by patterning the touch buffer layer 182 in the central area inside the contact hole CNT.

Thereafter, as shown in FIG. 8C, the metal is deposited over the entire substrate 140 and then etched to form the bridge electrode 192 on the touch buffer layer 182 of the display area AA.

Subsequently, the inorganic material such as SiOx or SiNx is deposited on the touch buffer layer 182 on which the bridge electrode 192 is formed, and the metal is deposited thereon and then etched to form touch electrodes 194a and 194b in the display area AA and the 3-1 touch link line LNK3-1 is formed in the bending area BA.

In some implementations, each of the touch electrodes 194a and 194b is electrically connected to the bridge electrode 192 through the contact hole formed in the touch buffer layer 182, and the 3-1 touch link line LNK3-1 is extended into the contact hole CNT of the first non-display area NA1 and is electrically connected to the 3-2 touch link line LNK3-2.

Thereafter, the touch buffer layer 182 and the touch interlayer insulating layer 184 above the bank layer BNK outside the contact hole CNT of the first non-display area NA1 are etched to expose the bank layer BNK to the outside as shown in FIG. 8D. In this case, the touch buffer layer 182 and the touch interlayer insulating layer 184 may be etched by the same etching process as those of the first encapsulation layer 162 and the third encapsulation layer 166 in the side end portions of the display apparatus 100.

The first encapsulation layer 162 and the third encapsulation layer 166 are patterned in the masking process, not the etching process, so that the first encapsulation layer 162 and the third encapsulation layer 166 are not formed in the bending area, but are formed in a portion of the first non-display area NA1 and in the second non-display area NA2, e.g., in side end portions of the display apparatus 100. Accordingly, the first encapsulation layer 162 and the third encapsulation layer 166 are exposed to the outside from the side end portion of the display apparatus 100, and the exposed first encapsulation layer 162 and the third encapsulation layer 166 become moisture penetration paths from the outside. To avoid the moisture penetration, the first encapsulation layer 162 and the third encapsulation layer 166 in the end portions of the display apparatus 100 can be removed. Therefore, although not shown in FIG. 8D, in the display apparatus of the present disclosure, the first encapsulation layer 162 and the third encapsulation layer 166 formed in the first non-display area NA1 and the second non-display area NA2 (e.g., in the end portions of display apparatus 100) are etched so that the first encapsulation layer 162 and the third encapsulation layer 166 are spaced apart from the side end of the display apparatus 100 by a predetermined distance to prevent the penetration of the moisture along the side end portion (i.e., along the outer edge portion) of the display apparatus.

In some implementations, the first encapsulation layer 162 and the third encapsulation layer 166 are etched before the touch buffer layer 182 is formed. However, in other implementations, the first encapsulation layer 162 and the third encapsulation layer 166 can be etched after the touch buffer layer 182 and the touch electrodes 194a and 194b are formed, so that the touch buffer layer 182 and the touch interlayer insulating layer 184 can be etched simultaneously with the first encapsulation layer 162 and the third encapsulation layer 166 to form the contact hole CNT from which the touch buffer layer 182 and the touch interlayer insulating layer 184 are removed on the bank layer BNK in the bending area BA.

Thereafter, as shown in FIG. 8E, the organic material is coated and etched to form the touch planarization layer 186 in the display area AA and the bending area BA. In some implementations, the touch planarization layer 186 is spaced apart from the side end of the display apparatus 100 by a predetermined distance, and in particular, the end of the touch planarization layer 186 is directly contacted with the upper surface of the bank layer BNK, which is exposed to the outside.

Since both the touch planarization layer 186 and the bank layer BNK are made of organic materials, the touch planarization layer 186 and the bank layer BNK are bonded at the boundary between the touch planarization layer 186 and the bank layer BNK. This can improve the bonding force between the touch planarization layer 186 and the bank layer BNK and help prevent delamination of the end portion of the touch planarization layer 186.

Subsequently, as shown in FIG. 8F, the organic material is coated and then etched to form the touch passivation layer 188 in the display area AA.

In some implementations, the side end portion of the first encapsulation layer 162 and the third encapsulation layer 166 can be etched after depositing the touch buffer layer 182 and the touch interlayer insulating layer 184. In general, a part of the touch buffer layer 182 and the touch interlayer insulating layer 184 in the bending area BA is removed, so that the bank layer BNK made of organic material is exposed to the outside. As a result, since the end of the touch planarization layer 186 made of the organic material is directly contacted with the upper surface of the bank layer BNK made of the organic material, it is possible to prevent the delamination of the touch planarization layer 186 due to a decrease of the adhesion at the boundary of the end of the touch planarization layer 186.

Further, in some implementations, the first encapsulation layer 162 and the third encapsulation layer 166 can be etched after forming the touch electrodes 194a and 194b and the 3-1 touch link line LNK31-1. Therefore, it is possible to prevent the formation of a residual metal layer on the upper surface of the bank layer BNK exposed to the outside, which can help prevent a reduction in adhesion between the touch planarization layer 186 and the bank layer BNK caused by residual metal layer, thereby more effectively preventing delamination of the touch planarization layer 186.

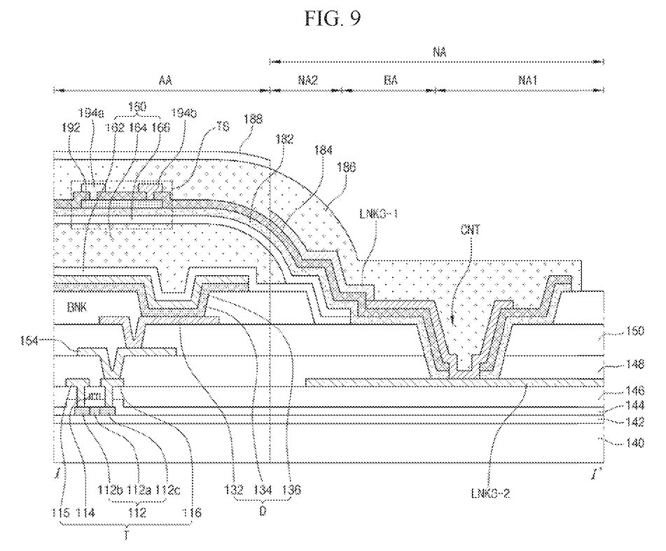

FIG. 9 is the view illustrating an example of the structure of the display apparatus 100 according to a second implementation of the present disclosure.

The difference between the display apparatus illustrated in FIG. 6 and the display apparatus of the present implementation is that the 3-2 link line LKN3-2 is disposed on the interlayer insulating layer 146. In this case, the 3-2 link line LKN3-2 may be made of the same material as the source electrode 115 and the drain electrode 116 of the thin film transistor T. Furthermore, the contact hole CNT is formed by removing the first planarization layer 148 and the second planarization layer 150, and the 3-1 link line LKN3-1 and the 3-2 link line LKN3-2 are electrically connected to each other in the contact hole CNT.

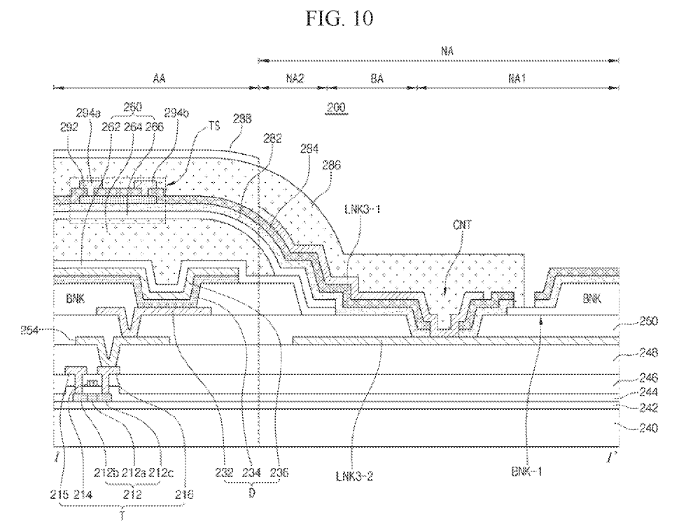

FIG. 10 is the view illustrating an example of the display apparatus 200 according to the third implementation of the present disclosure. In this case, the same configuration as the display apparatus 100 according to the first implementation of FIG. 6 is omitted or briefly described, and only other configurations are described in detail.

As shown in FIG. 10, the thin film transistor T and the light emitting device D are disposed in the display area AA, respectively, and the bank layer BNK is disposed in the display area AA and the non-display area NA.

A protruded portion BNK-1 is configured to protrude from the bank layer BNK disposed in the first non-display area NA1. For example, the protruded portion BNK-1 protrudes from the lower surface of the bank layer BNK and has a thickness smaller than that of the remaining portion of the bank layer BNK.

The touch buffer layer 282 and the touch interlayer insulating layer 284 above the protruded portion BNK-1 are removed so that a part of the protruded portion BNK-1 is exposed to the outside.

The touch planarization layer 286 is disposed on the touch sensor TS and protects the touch sensor TS. The touch planarization layer 286 is formed in the display area AA and extends to the second non-display area NA2, the bending area BA, and a partial area of the first non-display area NA1. The end of the touch planarization layer 286 is disposed directly on the upper surface of the protruded portion BNK-1 of the first display area NA1. As described above, in this implementation, since the end of the touch planarization layer 286 made of the organic material is disposed directly on and contacts the protruded portion BNK-1 of the bank layer BNK made of the organic material, the boundary characteristics between the touch planarization layer 286 and the protruded portion BNK-1 of the bank layer BNK may be improved to prevent the delamination of the touch planarization layer 286.

The above description and the accompanying drawings are merely illustrative of various implementations of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the implementations disclosed in the present disclosure are not intended to limit the technical spirit of the present disclosure, but to explain, and the scope of the technical spirit of the present disclosure is not limited by these implementations.

What is claimed is:

1. A display apparatus, comprising:
a substrate including a display area and a non-display area, wherein the display area has a plurality of sub-pixels and wherein the non-display area includes (i) a second non-display area disposed outside and adjacent to the display area, (ii) a first non-display area outside the second non-display area, and (iii) a bending area between the first non-display area and the second non-display area;
a bank layer disposed in the display area and in the non-display area;
a thin film transistor and a light emitting device disposed in each of the plurality of sub-pixels;
an encapsulation layer disposed above the light emitting device;
a touch sensor disposed on the encapsulation layer;
at least one link line extending from the non-display area to the touch sensor; and
a touch planarization layer disposed on and overlapping the touch sensor and the at least one link line,
wherein an end portion of the touch planarization layer in the non-display area is disposed directly on and contacts the bank layer in the non-display area.

2. The display apparatus of claim 1, wherein the at least one link line includes:
a first link line extended to the non-display area to be connected electrically to the touch sensor; and
a second link line connected electrically to the first link line in the non-display area to apply a touch signal to the first link line.

3. The display apparatus of claim 2, wherein the second link line is disposed in the first non-display area.

4. The display apparatus of claim 3, wherein the first link line and the second link line are connected to each other in the first non-display area or in the second non-display area.

5. The display apparatus of claim 2, wherein the thin film transistor includes a semiconductor layer, a gate insulating layer on the semiconductor layer, a gate electrode on the gate insulating layer, an interlayer insulating layer, and a source electrode and a drain electrode on the interlayer insulating layer, and
wherein the display apparatus further comprises a first planarization layer over the thin film transistor, a connection pattern to be connected electrically to the drain electrode on the first planarization layer, and a second planarization layer on the connection pattern.

6. The display apparatus of claim 5, wherein the second planarization layer has a contact hole therein, in which the first link line and the second link line are electrically connected to each other within the contact hole.

7. The display apparatus of claim 6, wherein the first link line is made of a same material as a touch electrode of the touch sensor, and
wherein the second link line is made of a same material as the connection pattern.

8. The display apparatus of claim 5, wherein a contact hole is formed in the first planarization layer and the second planarization layer, and the first link line and the second link line are electrically connected to each other within the contact hole.

9. The display apparatus of claim 8, wherein the first link line is made of a same material as a touch electrode of the touch sensor, and
wherein the second link line is made of a same material as the source electrode and the drain electrode.

10. The display apparatus of claim 1, wherein the touch planarization layer and the bank layer are made of an organic material.

11. The display apparatus of claim 1, further comprising a touch passivation layer disposed over the touch planarization layer in the display area.

12. The display apparatus of claim 1,
wherein the bank layer in the first non-display area includes a protruded portion that protrudes toward the bending area, and a thickness of the protruded portion of the bank layer is smaller than a thickness of a remaining portion of the bank layer, and
wherein the end portion of the touch planarization layer is disposed directly on and contacts the protruded portion of the bank layer in the first non-display area.

13. A method of fabrication a display apparatus, comprising:
providing a substrate including a display area and a non-display area, wherein the display area has a plurality of sub-pixels, and wherein the non-display area includes (i) a second non-display area disposed outside an adjacent to the display area, (ii) a first non-display area outside the second non-display area, and (iii) a bending area between the first non-display area and the second non-display area;
forming a first touch line in the non-display area;
forming a bank layer in the display area and in the non-display area, wherein the bank layer is formed between the sub-pixels of the display area;
providing a thin film transistor and a light emitting device in each of the sub-pixels;
forming an encapsulation layer over the light emitting device in the display area, wherein the encapsulation layer does not extend to the first non-display area;
forming a touch buffer layer on the encapsulation layer, wherein the touch buffer layer extends into the first non-display area;
etching the touch buffer layer of the first non-display area to expose a portion of the bank layer to an outside;
forming a touch sensor and a second touch line on the touch buffer layer; and
forming a touch planarization layer on the touch sensor and the second touch line;
wherein an end of the touch planarization layer is contacted with an upper surface of the exposed portion of the bank layer.

14. The method of claim 13, wherein the forming the encapsulation layer includes:
depositing an inorganic material over the light emitting device to form a first encapsulation layer;
depositing an organic material on a portion of the first encapsulation layer to form a second encapsulation layer;
depositing the inorganic material on the second encapsulation layer and a portion of the first encapsulation layer to form a third encapsulation layer; and
etching the first encapsulation layer and the third encapsulation layer of the non-display area.

15. The method of claim 13, further comprising forming a touch passivation layer on the touch planarization in the display area.

16. The method of claim 15, wherein the forming the touch passivation layer includes etching the touch passivation layer, and
wherein the touch buffer layer outside the touch planarization layer is etched simultaneously with the touch passivation layer being etched.

17. The display apparatus of claim 13, wherein the bank layer includes a protruded portion that protrudes towards the display area, and a thickness of the protruded portion is smaller than a thickness of a remaining portion of the bank layer, and
wherein the etching the touch buffer layer of the first non-display area includes etching the touch buffer layer over the protruded portion of the bank layer to be exposed to outside.
